(19) United States
(12) Patent Application Publication
(10) Pub. No.: US 2019/0067884 A1
(43) Pub. Date: Feb. 28, 2019

(54) INTELLIGENT DEVICE

(71) Applicant: HAN CHUANG INTERNATIONAL CO.,LTD., Taipei City (TW)

(72) Inventor: CHAO-HAN LI, Taipei City (TW)

(21) Appl. No.: 16/112,675

(22) Filed: Aug. 25, 2018

Related U.S. Application Data
(63) Continuation-in-part of application No. 15/693,470, filed on Aug. 31, 2017.

(51) Int. Cl. H01R 13/66; H05K 1/18; F21V 8/00; H01R 13/70; H01R 25/00; G01R 15/18

(52) U.S. Cl. CPC H01R 13/6683; H05K 1/181; G02B 6/0088; H01R 13/70; H01R 25/006; H05K 2201/10151; H05K 2201/1003; H05K 2201/10053; H05K 2201/09063; H05K 2201/10098; G01R 15/183

(57) ABSTRACT

The present invention provides an intelligent device, and the major aspect is using a design of an intelligent cover. The intelligent cover includes a circuit board which is provided with at least one induction coil, a microcontroller (MCU) and a switch. The induction coil is used to induce the amount of the current when the current is passed the induction coil, the open (non-conducting)/closed (conducting) state of the current transmission is controlled by the switch, and the MCU can monitor and remote control remotely, so that when the intelligent cover is combined with a base seat, which is capable of monitoring the electricity consumption, the voltage value and the temperature to achieve the reduction efficacy of the of monitoring costs.

### CROSS REFERENCE TO RELATED APPLICATIONS

The present application is a continuation in part of U.S. patent application Ser. No. 15/693,470, filed on Aug. 31, 2017, the disclosure of which is incorporated by reference herein.

### FIELD OF THE INVENTION

The present invention relates to an intelligent device, particularly relates to a design of an intelligent cover, the intelligent cover combines with a base seat that is capable of intelligently monitoring the effect of electricity consumption, the voltage value and the temperature to achieve the reduction efficacy of the monitoring costs, and is suitable for the socket device or the like into/on the wall.

### BACKGROUND OF THE INVENTION

Nowadays, the electricity consumption is rising year by year and the electricity bill is gradually increasing. Therefore, the energy saving and the power saving has become an important issue.

In recent years, there are many devices for monitoring the electricity consumption which has been developed to understand the electricity consumption. However, the most of the monitoring device is an external plug-in device, such as a socket, that is, the socket is to be plugged into the wall, when the socket is used to monitor the electricity consumption. But, the volume of the plug-in device is large and bulky, which is easy to occupy the using space of another socket. Thus, the plug-in socket for the monitoring the electricity consumption is very inconvenient.

Moreover, if every socket needs to monitor the electricity consumption, it needs to buy a lot of external plug-in devices to use. Generally, the consumers will not spend such money to do this. It is a major lack of promotion for monitoring the electricity consumption. In addition, in the space usage, when the external plug-in device is inserted into the socket on the wall, the external plug-in device will protrude from the wall. This protrusion would be affected the decoration of the cabinet or the bookcase, and the protrusion is not aesthetically pleasing for the overall space.

### SUMMARY OF THE INVENTION

The major objective of the present invention is to provide an intelligent device, and the major objective is using a design of an intelligent cover. The intelligent cover includes a circuit board. The circuit board includes an induction coil, a microcontroller (MCU), and a switch. The induction coil is used to induce the amount of the current that is passed through the induction coil. Next, the switch controls the open (non-conducting)/closed (conducting) state of the current transmission, so as to the MCU can monitor and remote control remotely. Thus, the intelligent cover is combined with a base seat that is capable of monitoring the electricity consumption, the voltage value, and the temperature to achieve the reduction efficacy of the monitoring costs, and to increase the overall utility.

Another objective of the present invention is to provide an intelligent device. By a built-in wireless transmission module in a microcontroller (MCU) of the circuit board, the intelligent device is communicated with at least one electronic device. The electronic device is a remote control unit, a tablet personal computer, a note book, a mobile phone, a personal digital assistant (PDA), or a smart bracelet. Thus, above electronic devices can remotely receive the monitored value, such as electricity consumption, the voltage value or the temperature, and intelligently statistic and analyze for immediate monitoring to increase overall convenience.

Another objective of the present invention is to provide an intelligent device. The intelligent device includes a base seat. The base seat includes an inner live wire loop and an outer live wire loop. The outer live wire loop is connected in series with a live wire inside the wall, in which the inner live wire loop includes a first sheet metal component, the outer live wire loop includes a second sheet metal component, and the switch is connected with the first sheet metal component of the inner live wire loop of the base seat and the second sheet metal component of the outer live wire loop. The switch is provided for controlling the open (non-conducting)/closed (conducting) state of the current transmission of the inner live wire loop of the base seat to increase the overall utility.

### BRIEF DESCRIPTION OF THE DRAWINGS

FIG. 1 is a schematic view of showing the separation of a socket cover and a circuit board of an intelligent cover of a first embodiment in accordance with the present invention;

FIG. 2 is a schematic view of showing the separation of an outer housing and a panel of an intelligent cover and a circuit board of a first embodiment in accordance with the present invention;

FIG. 3 is an exploded schematic view of component of an intelligent cover of a first embodiment in accordance with the present invention;

FIG. 4 is a schematic view of showing the elevation angle of an intelligent cover of a first embodiment in accordance with the present invention;

FIG. 5 is a schematic view of showing the separation of an intelligent cover and a base seat of a second embodiment in accordance with the present invention;

FIG. 6 is an exploded perspective view of component of a base seat of a second embodiment in accordance with the present invention;

FIG. 7 is a layout of showing an outer live wire loop, an inner live wire loop, an earth wire loop, and the neutral wire loop of the second embodiment in accordance with the present invention;

FIG. 8 is a schematic view of showing a second sheet metal component of an outer live wire loop and a first sheet metal component of an inner live wire loop combined with a circuit board of a second embodiment in accordance with the present invention; and

FIG. 9 is another view angle schematic of showing a second sheet metal component of an outer live wire loop and a first sheet metal component of an inner live wire loop combined with the circuit board of a second embodiment in accordance with the present invention.

### DETAILED DESCRIPTION OF THE PREFERRED EMBODIMENT

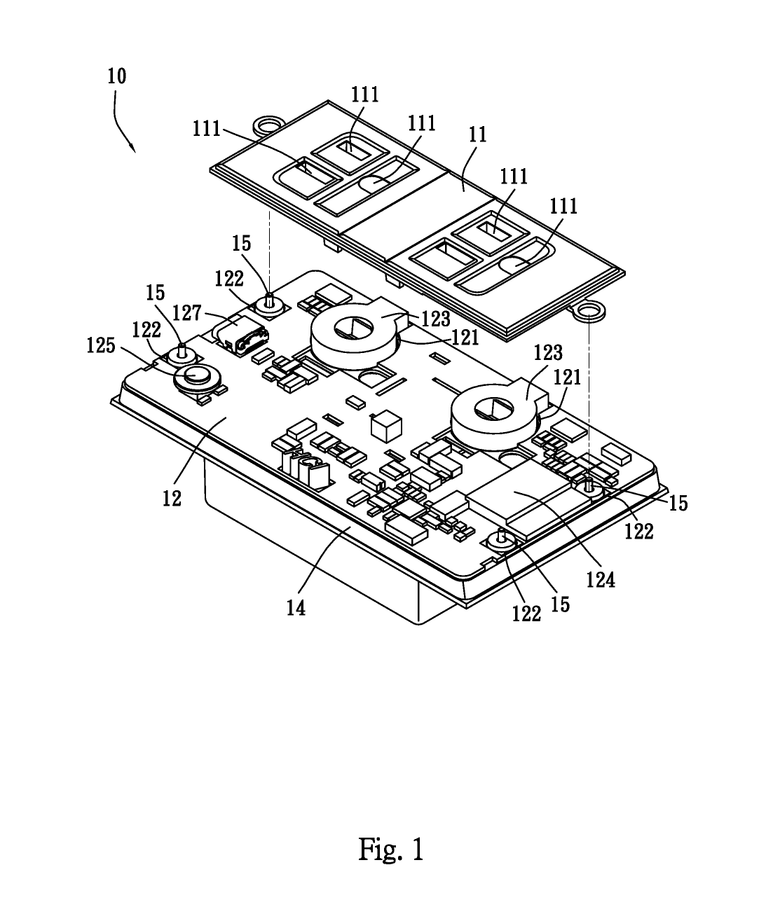

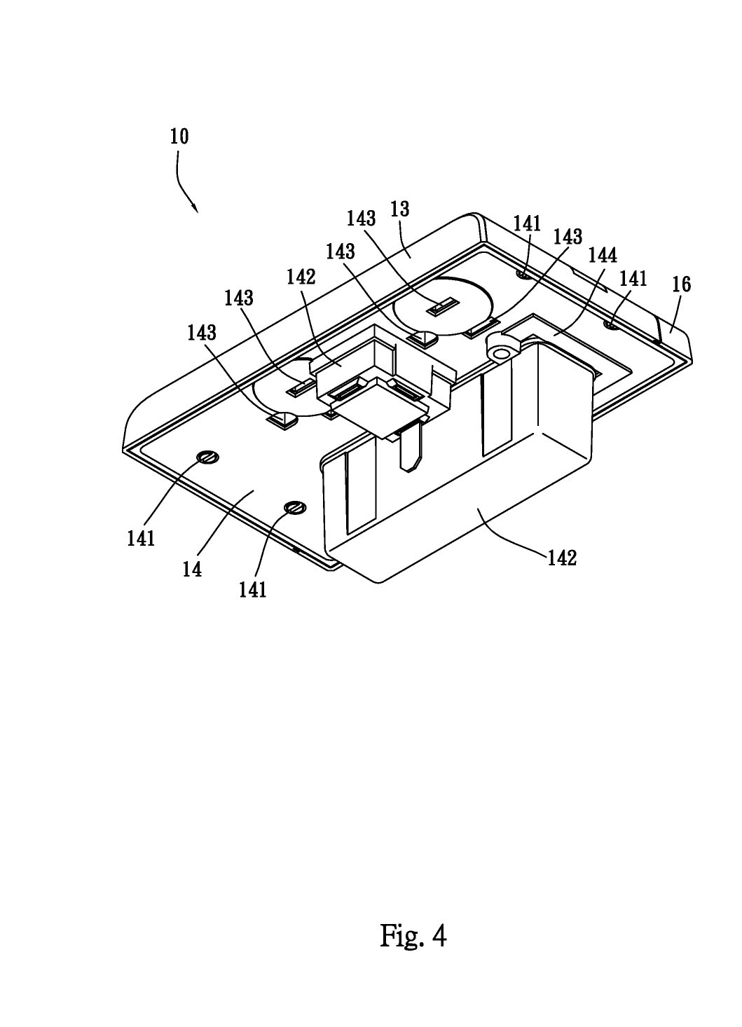

Please refer to FIG. 1 to FIG. 9 are schematic view of the embodiment of the present invention.

The first embodiment of an intelligent device of the present invention (as shown in FIG. 1 to FIG. 4) is an intelligent cover 10. The intelligent cover 10 includes a socket cover 11 and a circuit board 12 (as shown in FIG. 1). The socket cover 11 is provided with a hole 111 thereon such as a socket of a typical socket. The socket cover 111 is combined with the circuit board 12. The circuit board 12 is provided with a slot hole 121 at a position opposite to the hole 111 of the socket cover 11, the slot hole 121 is used to expose the copper piece of the socket (not shown).

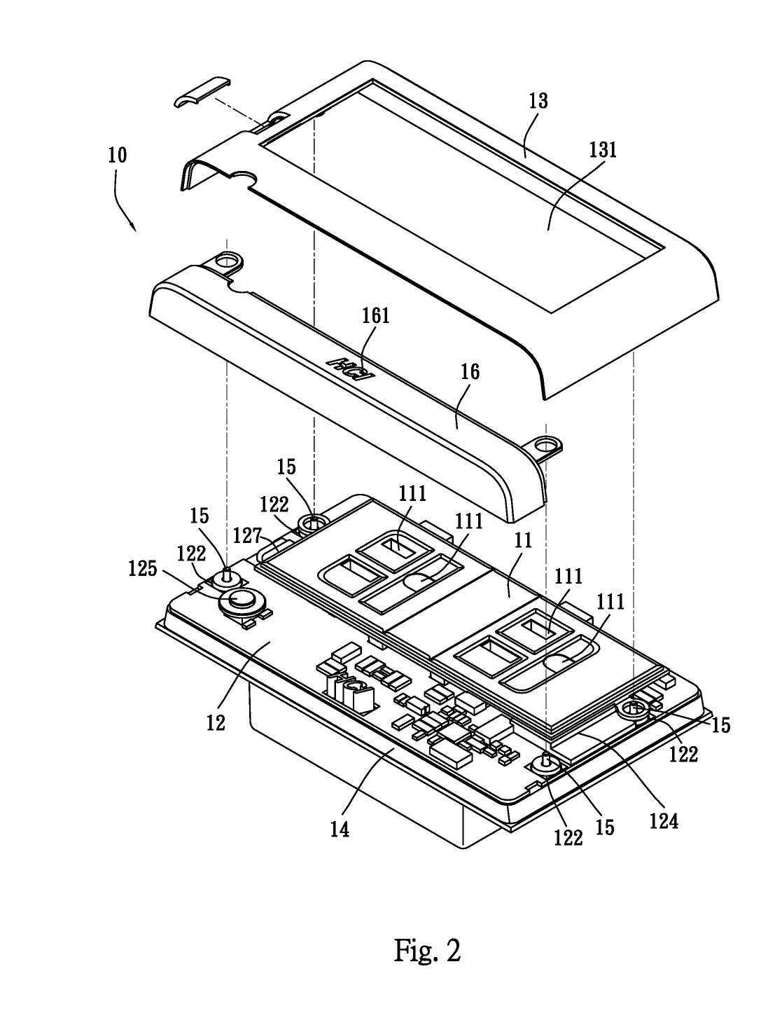

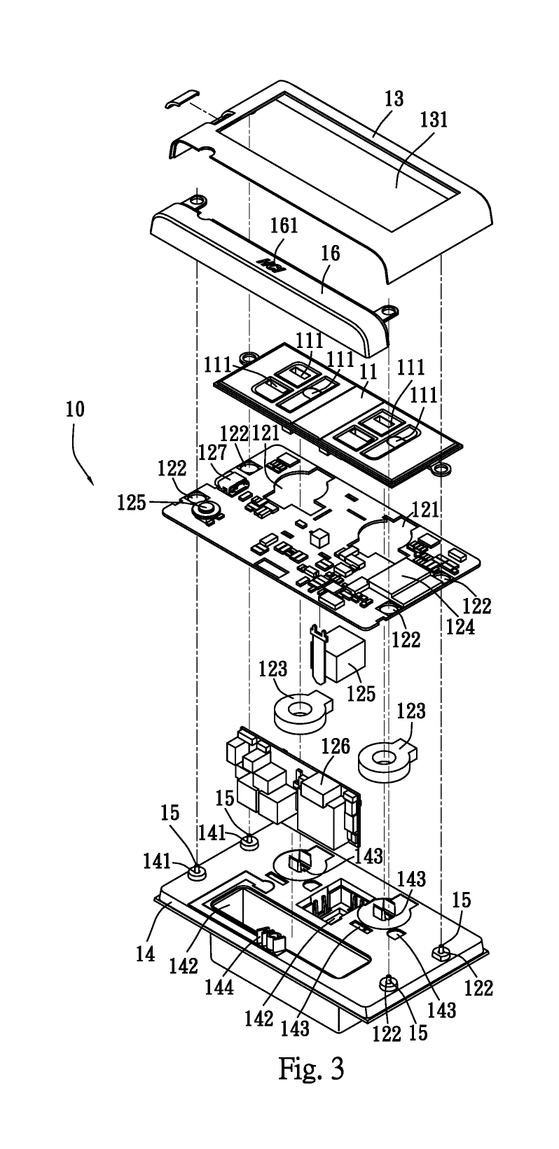

In addition, the intelligent cover 10 further includes an outer housing 13 and a cover seat 14 (as shown in FIG. 2). The outer housing 13 and the cover seat 14 are used to encapsulate the socket cover 11 and the circuit board 12 therein. The cover seat 14 is provided with at least one hole 141. The circuit board 12 is provided with a hole 122. Therefore, the circuit board 12 is fixed with the cover seat 14 by a coupling component 15 through the hole 141 of the cover seat 14 and the hole 122 of the circuit board 12, in which the coupling component 15 can be a screw. The cover seat 14 is recessed with at least one recess 142 (as shown in FIG. 3) to accommodate the object. The cover seat 14 is provided with a hole 143 at a position opposite to the hole 111 of the socket cover 11. In addition, the outer housing 13 is covered the top of the cover seat 14. The outer housing 13 includes a hollow surface 131 to expose the hole 111 of the socket cover 11.

The above cover seat 14 is further combined with a panel 16 that is provided a hollow font 161 thereon (as shown in FIG. 2 and FIG. 3). The cover seat 14 is provided with a light guiding plate 144 thereon (as shown in FIG. 3), which is disposed below the panel 16. The light guiding plate 144 can be configured as the hollow font 161 to transmit the light of the hollow font 161 of the panel 16 through the light guiding plate 144, such that the cover seat 14 has the ability of identification.

Moreover, the circuit board 12 of the intelligent cover 10 includes an induction coil 123, a microcontroller (MCU) 124, and a switch 125 (as shown in FIG. 1 and FIG. 3). The MCU 124 has the ability to integrate the memory and computing functions such as CPU, RAM, ROM, I/O or A/D. The number of the induction coil 123 is designed to correspond to the number of socket. The induction coil 123 is electrically connected with the MCU 124. The induction coil 123 is disposed below the socket cover 11 and disposed within the slot hole 121 of the circuit board 12 to induce the value of the current passing through the induction coil 123. The circuit board 12 is provided with a transformer 126 (as shown in FIG. 3), which is disposed within the recess hole 142 of the cover seat 14. The transformer 126 is used to convert the transmitted electricity into the required voltage, such that the circuit board 12 is to have different voltage to provide various electronic devices for operation.

In addition, the switch 125 of the circuit board 12 is electrically connected with the MCU 124, in which the switch 125 is a tractile switch, a push button switch, a slide switch, a push switch or a relay switch, or the combination thereof. In the preferred embodiment of the present invention, the switch 125 is composed of the push button switch plus the relay switch (as shown in FIG. 3). In addition to manually operating the push button switch, the MCU 124 can provide the remote control. The wireless transmission module (not shown) is built-in the MCU 124 for connecting with at least one electronic device (not shown), in which the electronic device is a remote control unit, a table personal computer, a note book, a mobile phone, a personal digital assistant (PDA), or a smart bracelet. Thereby, the electronic device can transmit signals to and from the MCU 124 to control the operation of the switch 125 directly, that is, the relay switch is used to control the open (non-conducting)/closed (conducting) state of the current transmission.

In addition, the circuit board 12 of the present invention is provided with at least one slot 127 (as shown in FIG. 1 and FIG. 3), such that the circuit board 12 is connected at least one external device through the slot 127 (not shown). The slot 127 is a Universal Serial Bus (USB) interface or other standard interfaces that conform to the serial bus (such as Mini USB interface, Micro USB interface, or Type-C interface). The external device is any one of an infrared detecting device, a signal control device, a display control device, or the like, or other device that can be connected through a standard interface of a serial bus bar to enable the intelligent cover 10 of the present invention to have an expanded performance, so that the intelligent cover 10 can have more application.

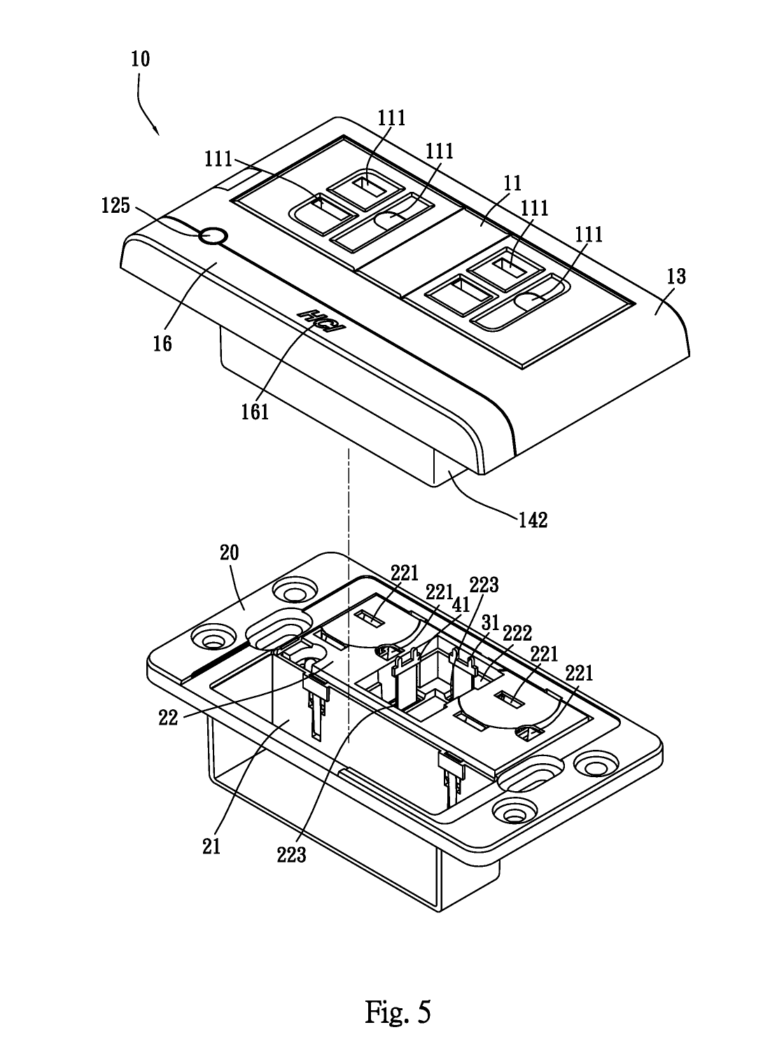

The second embodiment of an intelligent device of the present invention (as shown in FIG. 5 to FIG. 9) includes a base seat 20 and an intelligent cover 10 (as shown in FIG. 5). The design of the intelligent cover 10 is described as above first embodiment, and it will not repeatedly herein. The following description will detail explain the combination of the base seat 20 and the intelligent cover 10.

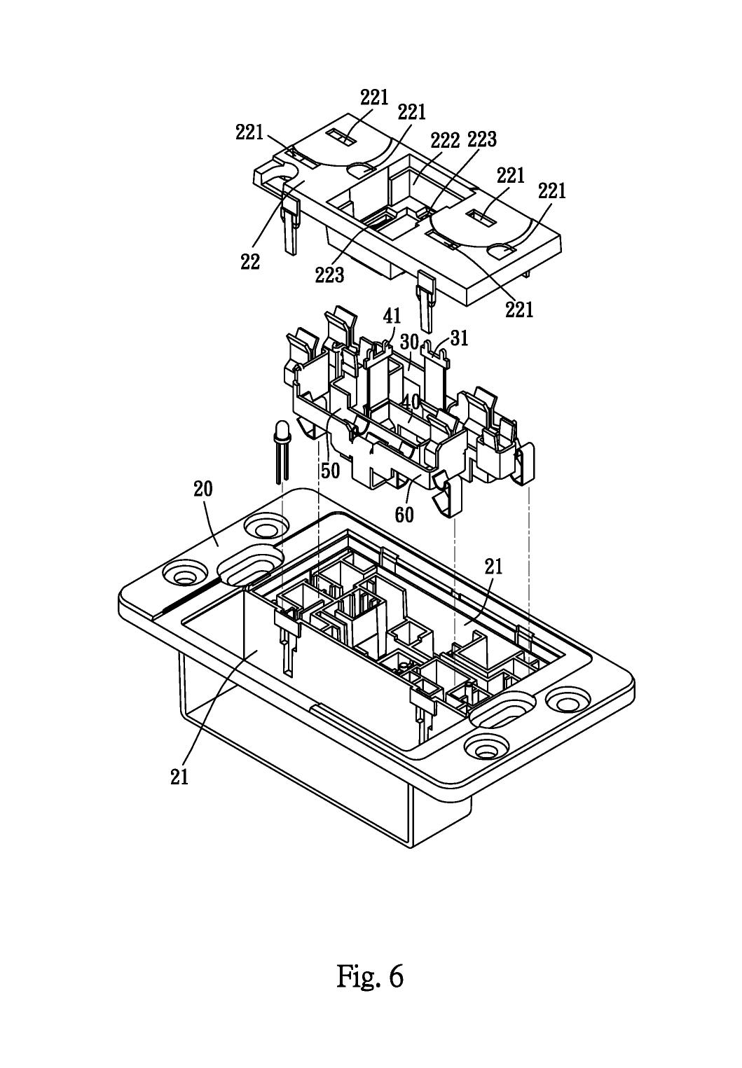

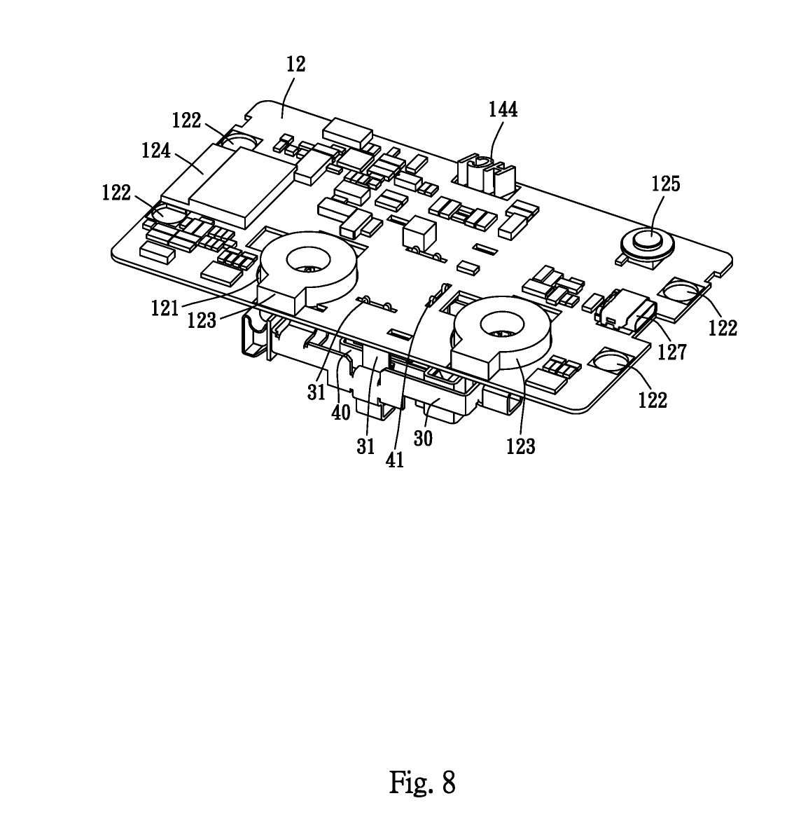

First, the base seat 20 is disposed into the wall (not shown). The base seat 20 is combined with cover seat 14 of the intelligent cover 10. The base seat 20 is provided with at least one recess 21 (as shown in FIG. 6). One of the recesses 21 is provided for accommodating the recess hole 142 of the cover seat 14, and the recess hole 142 is recessed for the transformer 126. The base seat 20 is further provided with another recess 21 for arranging an outer live wire loop 30 and an inner live wire loop 40. The top end of the outer live wire loop 30 and the inner live wire loop 40 is provided with a socket shell 22 (as shown in FIG. 6). The socket shell 22 is disposed below the cover seat 14 of the intelligent cover 10, and the socket shell 22 is provided with a hole 221 at a position corresponding to the hole 143 of the cover seat 14. The socket shell 22 is provided with a recess 222 to accommodate the relay switch of the switch 125 which is disposed on the circuit board 12 of the intelligent cover 10 (as shown in FIG. 8), and the recess 222 of the socket shell 22 is provided with at least one hole 223 therein.

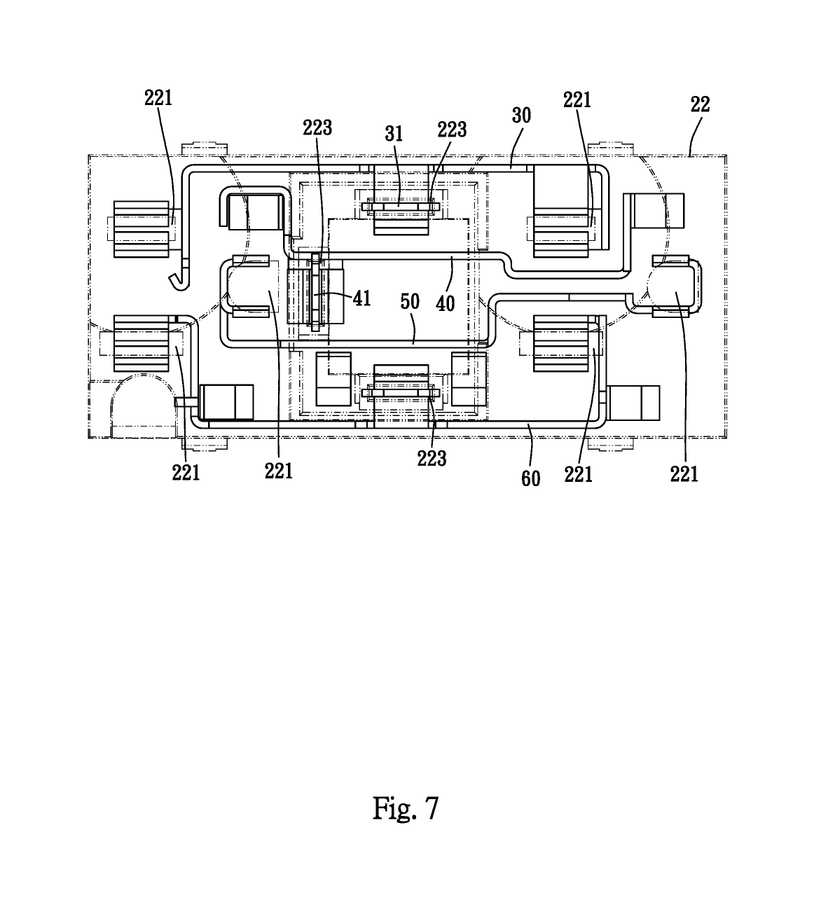

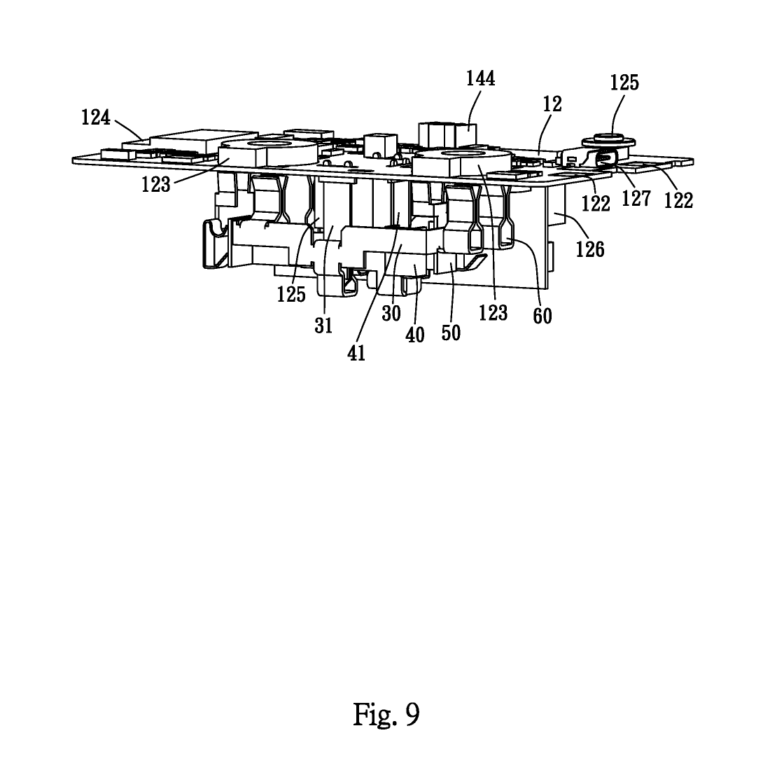

In addition, the outer live wire loop 30 is connected in series with the live wire in the wall (not shown) to receive the AC power transmitted by the power system of the main switch. The inner live wire loop 40 is provided with a first sheet metal component 41 and the outer live wire loop 30 is provided with a second sheet metal component 31 (as shown in FIG. 6), in which the first sheet metal component 41 and the second sheet metal component 31 are passed through all holes 223 of the recess 222 of the socket shell 22 (as shown in FIG. 7) and then attach the circuit board 12 of the intelligent cover 10 to form the connection (as shown in FIG. 8 and FIG. 9). On the one hand, the power can be transferred from the first sheet metal component 41 and the second sheet metal component 31 to the transformer 126 of the circuit board 12 for converting to a desired voltage, so that the circuit board 12 can have different voltages to provide various electronic devices for operation. On the other hand, the voltage or temperature of the inner live wire loop 40 and the outer live wire loop 30 can be monitored through the first sheet metal component 41 and the second sheet metal component 31. By the switch 125 of the circuit board 12 is connected the first sheet metal component 41 of the inner live wire loop 40 and the second sheet metal component 31 of the outer live wire loop 30, the switch 125 can control the open (non-conducting)/closed (conducting) state of current transmission of the inner live wire loop 40 of the base seat 20.

In addition to the abovementioned circuit, the recess 21 of the base seat 21 is also provided with an earth wire loop 50 and a neutral wire loop 60 (as shown in FIG. 7), in which the neutral wire loop 60 is connected in series with the neutral wire in the wall, such that the current can be returned to the power system of the main switch, the potential of which is usually equal (or close to) zero, and the earth wire loop 40 is connected in series with the earth equipotential conductor to avoid the leakage current to damage the equipment or the human beings.

Thereby, when an electronic product requires power to actuate (not shown), the plug is inserted into the hole 111 of the socket cover 11 of the intelligent cover 10, such that the metal terminal of the plug can pass through the induction coil 123 below the socket cover 11, and through the hole 143 of the cover seat 14 of the intelligent cover 14 and the hole 221 of the socket shell 22 under the cover seat 14 of the intelligent cover 10 to connect the inner live wire loop 40, the outer live wire loop 30, the neutral wire loop 60 and the earth wire loop 50 which is arranged under the socket shell 22 to obtain the required power. The circuit board 12 of the intelligent cover 10 is used to monitor the electricity consumption, the voltage value, and the temperature, and the MCU 124 remotely receives the monitored value for intelligently statistics and analysis. The MCU 124 has a capability of remotely controlling the open (non-conducting)/closed (conducting) state of the current transmission of the switch 125.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. An intelligent device, comprising:
a base seat, the based is disposed in a wall, the base seat includes an inner live wire loop and an outer live wire loop, the outer live wire loop is connected in series with a live wire inside the wall, wherein the inner live wire loop is provided with a first sheet metal component and the outer live wire loop is provided with a second sheet metal component; and
an intelligent cover, the intelligent cover is combined with the base seat, the intelligent cover includes a socket cover and a circuit board, the socket cover is connected the circuit board, wherein the circuit board includes at least an induction coil, a microcontroller (MCU) and a switch, the induction coil is electrically connected with the microcontroller, and the induction coil is disposed between the socket cover and the outer live wire loop of the base seat to induce the current value which is passed the induction coil, the switch is electrically connected with the microcontroller, and is electrically connected with the first sheet metal component of the inner live wire loop of the base seat and the second sheet metal component of the outer live wire loop, and the switch is provided for controlling the open (non-conducting)/closed (conducting) state of the current transmission of the inner live wire loop of the base seat.

2. The intelligent device according to claim 1, wherein the first sheet metal component includes a outer housing and a cover seat, the outer housing is attached to the cover seat, the outer housing includes a hollow surface to expose outside the socket cover, the cover seat is provided with at least a hole and the circuit board is provided with a hole, and the circuit board is fixed with the cover seat by a coupling component through the hole of the circuit board and the hole of the cover seat.

3. The intelligent device according to claim 2, wherein the cover seat is combined with a panel, the panel is provided with a hollow font thereon, and a top of the cover seat is provided with a light guiding plate, and the light guiding plate is disposed below the panel.

4. The intelligent device according to claim 1, wherein the circuit board includes a slot for connecting with at least one external device, and the slot is a Universal Serial Bus (USB) interface.

5. The intelligent device according to claim 1, wherein the microcontroller of the circuit board includes a built-in wireless transmission module for connecting to at least one electronic device through the wireless transmission module.

6. The intelligent device according to claim 5, wherein the electronic device is a remote control unit, a tablet personal computer, a note book, a mobile phone, a personal digital assistant (PDA), or a smart bracelet.

7. The intelligent device according to claim 1, wherein the circuit board includes a transformer device for converting the power transmitted by the outer live wire loop of the base seat to a desired voltage.

8. The intelligent device according to claim 1, wherein the switch is a tractile switch, a push switch, a slide switch, a push button switch or a relay switch, or the combination thereof.

9. The intelligent device according to claim 1, wherein a neutral wire loop is disposed over the base seat, and the neutral wire loop is connected in series with a neutral wire inside the wall.

10. The intelligent device according to claim 1, wherein an earth wire loop is disposed over the base seat.

11. An intelligent device, which is an intelligent cover and the intelligent cover comprises:
a socket cover; and
a circuit board, the socket cover is coupled over the socket cover, wherein the circuit board includes at least an induction coil, a microcontroller, and a switch, the induction coil is electrically connected with the microcontroller, and the induction coil is disposed on the bottom of the socket cover to induce the current value which is passed through the induction coil, the switch is electrically connected with the microcontroller for controlling the open (non-conducting)/closed (conducting) state of the current transmission by the switch.

12. The intelligent device according to claim 11, wherein the intelligent cover includes an outer housing and a cover seat, the outer housing is attached to the cover seat, the outer housing includes a hollow surface to expose outside the socket cover, the cover seat is provided with at least a hole and the circuit board is provided with a hole, and the circuit board is fixed with the cover seat by a coupling component through the hole of the circuit board and the hole of the cover seat.

13. The intelligent device according to claim 12, cover seat is combined with a panel, the panel is provided with a hollow font thereon, and a top of the cover seat is provided with a light guiding plate, and the light guiding plate is disposed on the bottom of the panel.

14. The intelligent device according to claim 11, wherein the circuit board includes a slot for connecting with at least one external device, and the slot is a Universal Serial Bus (USB) interface.

15. The intelligent device according to claim 11, wherein the microcontroller of the circuit board includes a built-in wireless transmission module for connecting to at least one electronic device through the wireless transmission module.

16. The intelligent device according to claim 15, wherein the electronic device is a remote control unit, a tablet personal computer, a note book, a mobile phone, a personal digital assistant (PDA), or a smart bracelet.

17. The intelligent device according to claim 11, wherein the circuit board includes a transformer device for converting the power transmitted by the outer live wire loop of the base seat to a desired voltage.

18. The intelligent device according to claim 11, wherein the switch is a tractile switch, a push switch, a slide switch, or a push button switch.
